(19) United States
(12) Patent Application Publication
(10) Pub. No.: US 2019/0242930 A1
(43) Pub. Date: Aug. 8, 2019

(54) CURRENT DETECTION APPARATUS

(71) Applicant: DENSO TEN Limited, Kobe-shi (JP)

(72) Inventor: Masato HISANAGA, Kobe-shi (JP)

(73) Assignee: DENSO TEN Limited, Kobe-shi (JP)

(21) Appl. No.: 16/260,330

(22) Filed: Jan. 29, 2019

(30) Foreign Application Priority Data
Feb. 5, 2018 (JP) 2018-018599

(51) Int. Cl. G01R 19/165; G01R 1/44; G01R 19/25

(52) U.S. Cl. CPC G01R 19/16528; G01R 1/44; G01R 19/2516; G01R 19/2513; G01R 19/2506

(57) ABSTRACT

A current detection apparatus includes a microcomputer. The microcomputer is configured to: detect a first current by using a first current sensor having a first current detection range; detect a second current by using a second current sensor having a smaller current detection error with respect to temperature change than the first current sensor and having a second current detection range different from the first current detection range and partially overlapping the first current detection range; calculate a correction value based on the second current that has been detected in a range in which the first current detection range and the second current detection range overlap with each other, and correct the first current by the correction value when using the first current for a detection current to be detected.

### BACKGROUND OF THE INVENTION

### Field of the Invention

The invention relates to a technology of a current detection apparatus for detecting a current.

### Description of the Background Art

Conventionally, the current detection apparatus for detecting a wide range of currents using a current sensor for a small current and a current sensor for a large current has been known.

However, the current detection apparatus is not designed to consider a current detection error of the current sensor due to temperature change. Thus, in the current detection apparatus, the current detection error increases due to temperature change so that current detection accuracy of the current sensor might decrease. Therefore, a current detection apparatus having high accuracy in detecting a current is desired.

### SUMMARY OF THE INVENTION

According to one aspect of the invention, a current detection apparatus includes a microcomputer. The microcomputer is configured to: detect a first current by using a first current sensor having a first current detection range; detect a second current by using a second current sensor having a smaller current detection error with respect to temperature change than the first current sensor and having a second current detection range different from the first current detection range and partially overlapping the first current detection range; calculate a correction value based on the second current that has been detected in a range in which the first current detection range and the second current detection range overlap with each other; and correct the first current by the correction value when using the first current for a detection current to be detected.

Thus, it is possible to improve current detection accuracy.

Therefore, an object of the invention is to provide a technology that can improve the current detection accuracy in the current detection apparatus for detecting a current.

These and other objects, features, aspects and advantages of the invention will become more apparent from the following detailed description of the invention when taken in conjunction with the accompanying drawings.

### BRIEF DESCRIPTION OF THE DRAWINGS

FIG. 1 illustrates an outline of a current detection method according to an embodiment;

FIG. 2 is a block diagram illustrating an outline of a power supply system;

FIG. 3 is a block diagram illustrating an outline of a controller;

FIG. 4 is a flowchart illustrating current detection control;

FIG. 5 is a flowchart illustrating calculation and control of a gain correction value; and

FIG. 6 illustrates a relation between an actual current and a current that is detected by a current sensor.

### DESCRIPTION OF THE EMBODIMENTS

In the following, an embodiment of a current detection apparatus disclosed in the application will be described with reference to the accompanying drawings. The invention is not limited to the embodiment described in the following.

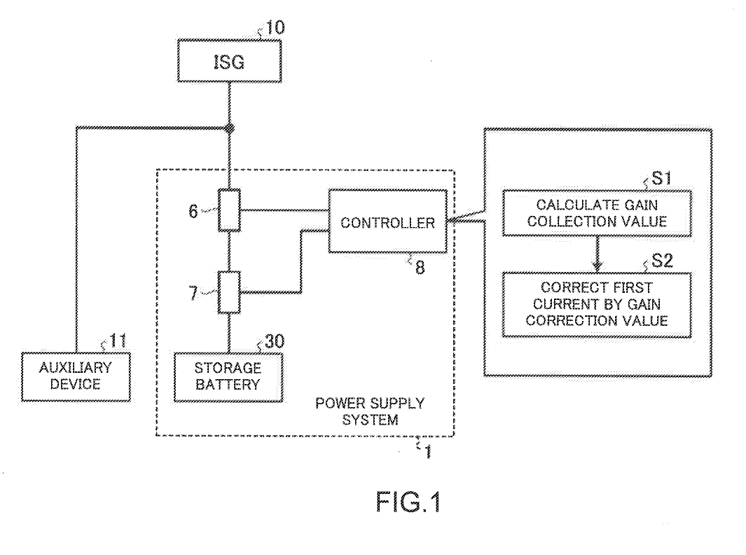

First, description will be made on an outline of a current detection method that is executed by the current detection apparatus according to the embodiment with reference to FIG. 1. FIG. 1 is a diagram illustrating an outline of the current detection method according to the embodiment.

A controller 8 as the current detection apparatus is mounted on a power supply system 1 of a hybrid vehicle and detects a current when a storage battery 30 charges and discharges. The hybrid vehicle having an engine will be described as one example. However, the invention is not limited thereto. The power supply system 1 may be mounted on an electric vehicle.

The storage battery 30 is, for example, a lithium-ion battery or a capacitor, and supplies power to an integrated starter generator (ISG) 10 or an auxiliary device 11. Furthermore, the storage battery 30 is supplied with power generated by the ISG 10 and charged. The storage battery 30 may be supplied with power from an external power supply and charged.

The ISG 10 functions as a starting apparatus for starting the engine (not illustrated). The ISG 10 generates a driving force when a vehicle travels. The ISG also functions as a motor generator for generating regenerated power by regenerative braking when the vehicle decelerates. The auxiliary device 11 is, for example, a navigation apparatus, an audio or an air conditioner.

When supplying power to the auxiliary device 11, a small current of a few A flows into the power supply system 1. In the power supply system 1, for example, when supplying power to the ISG 10, a large current of several hundred A flows. Therefore, the controller 8 detects a wide range of currents using a first current sensor 6 and a second current sensor 7. The controller 8 detects a current flowing when the storage battery 30 charges and discharges as a detection current to be detected.

The first current sensor 6 is provided to detect the small current. The first current sensor 6 is, for example, a hall-type current sensor for detecting a current from a change in a magnetic field caused by a current flowing through an energizing path. The first current sensor 6, for example, has a first current detection range of 0 A to 100 A.

The hall-type current sensor has the first current detection range which is relatively narrow. Thus, an LSB of an A/D converted value decreases so that the hall-type current sensor can accurately detect the small current. However, the hall-type current sensor has a large current detection error with respect to temperature change.

The second current sensor 7 is provided to detect the large current. The second current sensor 7 is, for example, a shunt-type current sensor for detecting a current from a voltage change before and after a resistance inserted in the energizing path. The second current sensor 7 has a second current detection range different from the first current detection range of the first current sensor 6. The second current detection range is wider than the first current detection range and is, for example, a range of 0 A to 750 A.

The shunt-type current sensor has a smaller current detection error with respect to temperature change than the hall-type current sensor. However, in the shunt-type current sensor, since the second current detection range is wider than the first current detection range, the LSB of the A/D converted value increases. Thus, the shunt-type current sensor cannot accurately detect the small current. In order to accurately detect the small current, a resistance value should be increased. When the resistance value of the shunt-type current sensor is increased, a loss due to the resistance increases. Therefore, in the power supply system 1, in order to reduce the loss due to the resistance, the second current sensor 7 that has a small resistance value is used.

In the following, a current detected by the first current sensor 6 is referred to as a “first current” and a current detected by the second current sensor 7 is referred to as a “second current”. When the first current falls within the first current detection range, that is, the first current is smaller than an upper limit current in the first current detection range, the controller calculates the detection current using the current detected by the first current sensor 6. When the first current falls outside the first current detection range, that is, the first current is equal to or larger than the upper limit current in the first current detection range, the controller 8 uses the current detected by the second current sensor 7 as the detection current.

When the controller 8 calculates the detection current using the first current, the controller 8 corrects the first current by a gain correction value that is a correction value based on the second current so as to reduce a current detection error with respect to temperature change.

The controller 8 detects the first current and the second current in a range in which the first current detection range and the second current detection range overlap with each other, and calculates the gain correction value (a step S1). The controller 8 calculates the gain correction value by dividing the second current by the first current or subtracting the first current from the second current based on the first current and the second current.

When the controller 8 calculates the detection current using the first current, the controller 8 corrects the first current by the gain correction value (a step S2). The controller 8 sets a value obtained by multiplying the first current by the gain correction value as the detection current.

Thus, when the controller 8 calculates the detection current using the first current, the controller 8 can calculate the detection current with a small current detection error with respect to temperature change. That is, the controller 8 can improve current detection accuracy.

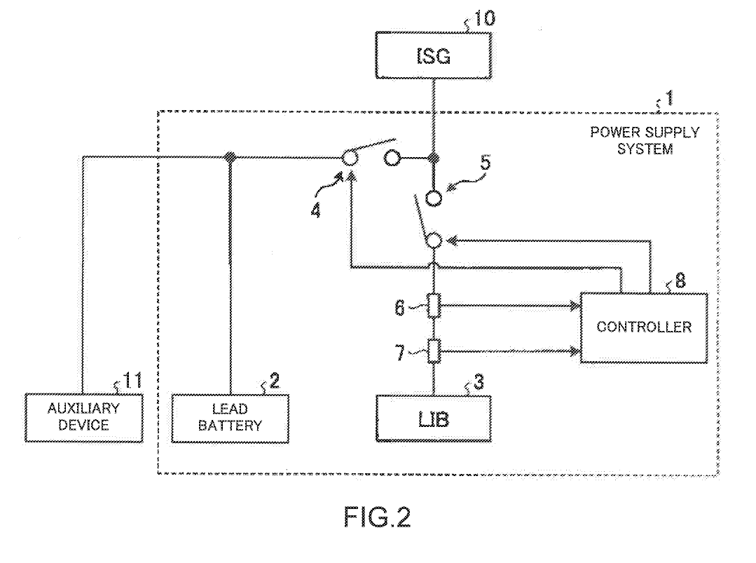

Next, description will be made on the power supply system 1 according to the embodiment with reference to FIG. 2. FIG. 2 is a block diagram illustrating a configuration example of the power supply system 1 according to the embodiment.

The power supply system 1 includes a lead battery 2, an LIB 3, a first switch 4, a second switch 5, the first current sensor 6, the second current sensor 7 and the controller 8.

The lead battery 2 is a secondary battery using lead for an electrode. The lead battery 2 is supplied with power generated by the ISG 10 and charged. The lead battery 2 supplies the power to the auxiliary device 11. The lead battery 2 supplies the power to the ISG 10 when the ISG starts the engine (not illustrated).

The LIB 3 is a secondary battery using a lithium-ion battery. The LIB 3 is supplied with power generated by the ISG 10 and charged. The LIB 3 supplies the power to the ISG 10 when the ISG 10 generates a driving force for the vehicle. The LIB 3 supplies the power to the auxiliary device 11 when a state-of-charge (SOC) of the lead battery 2 is smaller than a predetermined SOC or the power is supplied from the lead battery 2 to the ISG 10 to start the engine. The LIB 3 is the storage battery 30 illustrated in FIG. 1.

Each of the first switch 4 and the second switch 5 is a relay for controlling a short circuit and an open circuit. The first switch 4 is connected between the lead battery 2 and the ISG 10. The second switch 5 is connected between the LIB 3 and ISG 10. One end of the first switch 4 is connected to one end of the second switch 5, and ON and OFF states are controlled by the controller 8.

The controller 8 communicates with a vehicle control apparatus (not illustrated) provided in the vehicle. The controller 8 calculates the SOC of the LIB 3 and transmits a signal related to the calculated SOC to the vehicle control apparatus. The controller 8 calculates the SOC of the LIB 3 based on a voltage of the LIB 3, a temperature near the LIB 3 and a current flowing through a circuit between the LIB 3 and the second switch 5. The controller 8 opens or closes the first switch 4 and the second switch 5 based on the signal transmitted from the vehicle control apparatus.

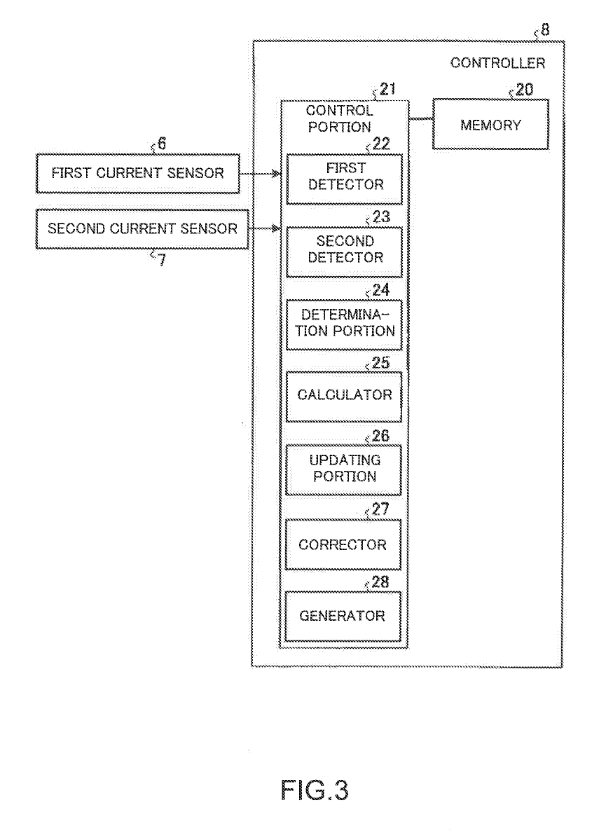

Next, description will be made on the controller 8 with reference to FIG. 3, FIG. 3 is a block diagram illustrating a configuration example of the controller 8 according to the embodiment. Here, description will be made on a configuration that functions as the current detection apparatus in FIG. 1, and other configurations, for example, a configuration that calculates the SOC of the LIB 3, will be omitted.

The controller 8 includes a memory 20 and a control portion 21. The memory 20 is, for example, a memory device, such as a random access memory (RAM) or a data flash memory. The memory 20 stores the gain correction value, information of various programs and the like.

The control portion 21, for example, includes a microcomputer which has a central processing unit (CPU), a read only memory (ROM), the RAM, input and output ports and the like, and various circuits. A part or entire of the control portion 21 may be configured by a hardware, such as an application specific integrated circuit (ASIC) or a field programmable gate array (FPGA).

The control portion 21 uses the RAM as a work area to execute a program stored in the ROM (not illustrated). The control portion 21 includes a plurality of processors that function by executing this program. Specifically, the control portion 21 includes a first detector 22, a second detector 23, a determination portion 24, a calculator 25, an updating portion 26, a corrector 27 and a generator 28. The control portion 21 may be configured by a plurality of control portions. Each processor may be configured by a plurality of processors. Each processor may be integrated and configured.

The first detector 22 A/D converts a signal from the first current sensor 6 and detects the first current as a digital value. The first detector 22 converts an analog value detected in a current detection range of the first current sensor 6 to a digital value with a preset number of bits, for example, 12 bits.

The second detector 23 A/D converts a signal from the second current sensor 7 and detects the second current as a digital value. The second detector 23 converts an analog value detected in a current detection range of the second current sensor 7 to a digital value with a preset number of bits, for example, 12 bits.

The first detector 22 detects the first current at the same timing as when the second detector 23 detects the second current. The first detector 22 and the second detector 23 may be configured by one detector.

The determination portion 24 determines whether or not the first current falls within the first current detection range. When the first current falls within the first current detection range, that is, the first current is smaller than the upper limit current in the first current detection range, the determination portion 24 sets the current flowing through the circuit between the LIB 3 and the second switch 5 as the detection current. The determination portion 24 determines that the controller 8 uses this detection current as the first current.

When the first current falls outside the first current detection range, that is, the first current is equal to or larger than the upper limit current in the first current detection range, the determination portion 24 sets the current flowing through the circuit between the LIB 3 and the second switch 5 as the detection current. The determination portion 24 determines that the controller 8 uses this detection current as the second current. The determination portion 24 may determine whether or not the second current falls within the first current detection range.

When the first current falls within the first current detection range, the determination portion 24 further determines whether or not the first current is larger than a predetermined threshold value. The predetermined threshold value is a preset value and a value near the upper limit current in the first current detection range. The predetermined threshold value is, for example, a value that is 10% smaller than the upper limit current in the first current detection range. When the first current detection range is 0 A to 100 A, the predetermined threshold value is 90 A. When the first current is larger than the predetermined threshold value, the determination portion 24 determines whether or not a calculation number of times of a current ratio described later has reached a predetermined number of times. The predetermined number of times is a preset number of times.

When it is determined that the first current falls within the first current detection range and the first current is larger than the predetermined threshold value, the calculator 25 calculates the current ratio by dividing the second current by the first current. The calculator 25 calculates the current ratio based on the first current and the second current that have been detected in the range in which the first current detection range and the second current detection range overlap with each other. The calculated current ratio is stored in the memory 20. The first current and the second current that are used for calculating the current ratio are respective currents that have been detected by the first detector 22 and the second detector 23 in the same timing.

The calculator 25 calculates the calculation number of times of the current ratio, and when the calculation number of times reaches the predetermined number of times, the calculator 25 calculates the gain correction value. Specifically, the calculator 25 calculates an average value of the current ratio that has been calculated the predetermined number of times, and sets the average value as the gain correction value. The calculator 25 resets the calculation number of times when the calculation number of times reaches the predetermined number of times.

The calculator 25 may calculate the gain correction value based on a difference between the first current and the second current instead of the current ratio.

When the calculation number of times reaches the predetermined number of times, the updating portion 26 overwrites the current ratio used when calculating the average value with a newly calculated current ratio, and updates the current ratio. That is, the updating portion 26 sequentially updates the current ratio of the predetermined number of times that is stored in the memory 20.

When the gain correction value has been calculated by the calculator 25, the updating portion 26 overwrites the gain correction value that is presently stored in the memory 20 with the calculated gain correction value. An overwriting process updates the gain correction value. The gain correction value is set to “1.0” as an initial value.

When the first current falls within the first current detection range, the corrector 27 corrects the first current by multiplying the first current that is used as the detection current by the gain correction value so as to calculate the detection current.

When the first current falls within the first current detection range, the generator 28 generates a signal related to the detection current calculated by the corrector 27. When the first current falls outside the first current detection range, the generator 28 sets the second current as the detection current and generates the signal related to the detection current.

The controller 8 calculates the SOC of the LIB 3 based on the generated signal related to the detection current and the like. The controller 8 can accurately detect the SOC of the LIB 3 by performing a coulomb counting using the detection current.

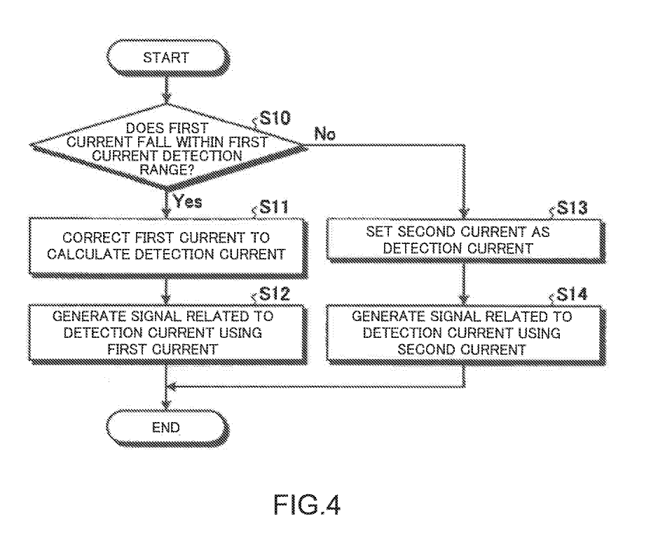

Next, description will be made on current detection control according to the embodiment with reference to FIG. 4. FIG. 4 is a flowchart illustrating the current detection control.

The controller 8 determines whether or not the first current falls within the first current detection range (a step S10). When the first current falls within the first current detection range (Yes in the step S10), the controller 8 corrects the first current by multiplying the first current by the gain correction value so as to calculate the detection current (a step S11). The controller 8 generates the signal related to the detection current using the first current (a step, S12).

When the first current falls outside the first current detection range (No in the step 10), the controller 8 sets the second current as the detection current (a step S13), and generates the signal related to the detection current using the second current (a step S14).

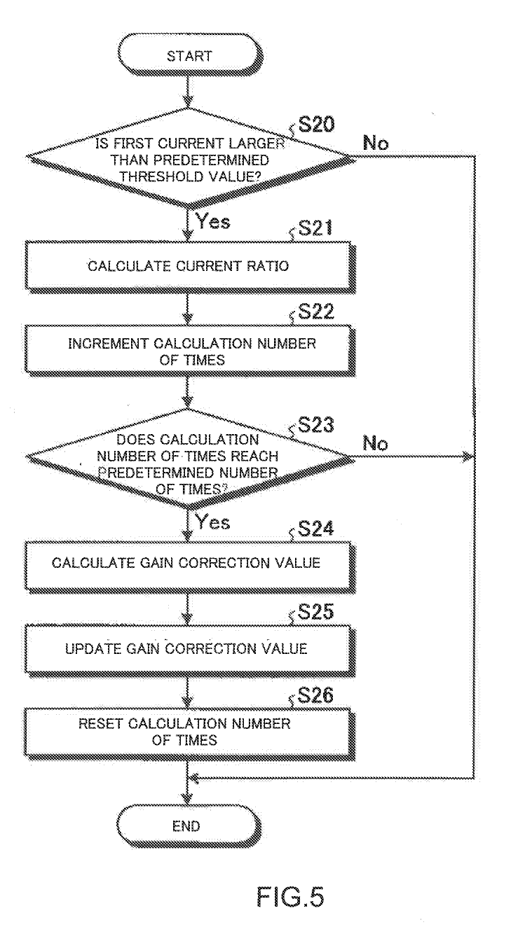

Next, description will be made on calculation and control of the gain correction value according to the embodiment with reference to FIG. 5. FIG. 5 is a flowchart illustrating the calculation and control of the gain correction value.

The controller 8 determines whether or not the first current is larger than the predetermined threshold value (a step S20).

When the first current is larger than the predetermined threshold value (Yes in the step 20), the controller 8 calculates the current ratio (a step S21), and increments the calculation number of times (a step S22).

When the calculation number of times reaches the predetermined number of times (Yes in a step S23), the controller 8 calculates the gain correction value (a step S24), and updates the gain correction value (a step S25). The controller 8 resets the calculation number of times (a step S26).

When the first current is equal to or smaller than the predetermined threshold value (No in the step S20), or the calculation number of times is smaller than the predetermined number of times (No in the step S23), the controller 8 ends a process.

The controller 8 may also calculate the current ratio based on the first current and the second current that have been detected when the first current falls within the first current detection range, regardless of whether or not the first current is larger than the predetermined threshold value.

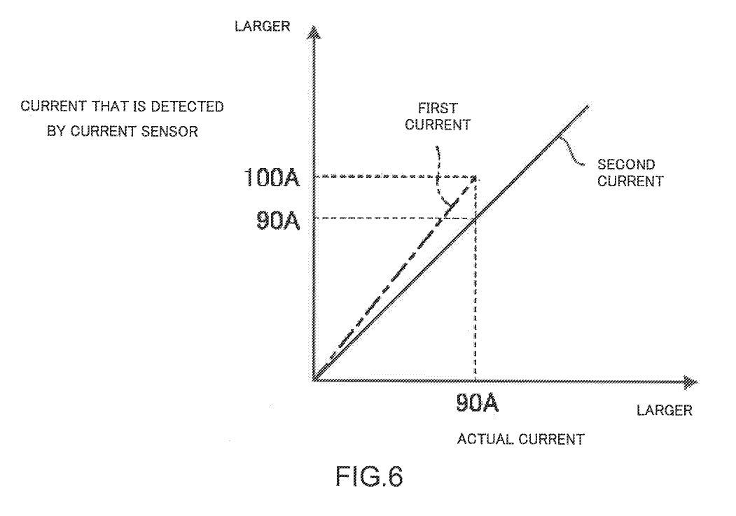

FIG. 6 is a diagram illustrating a relation between an actual current and a current that is detected by a current sensor. The first current sensor 6 has a larger current detection error with respect to temperature change than the second current sensor 7. Thus, for example, as illustrated in FIG. 6, the first current becomes larger than the actual current. In FIG. 6, the second current sensor 7 has no current detection error. For example, when the actual current is 90 A, the second current of 90 A is detected. On the other hand, in the first current sensor 6, when the actual current is 90 A, the first current of 100 A is detected.

The controller 8 calculates the gain correction value based on the second current that has been detected in the range in which the first current detection range and the second current detection range overlap with each other. Specifically, as illustrated in FIG. 6, when the first current detection range is set to 100 A or smaller, the controller 8 calculates the gain correction value by dividing the second current by the first current based on the second current detected in the range of 100 A or smaller, which is the range in which the first current detection range and the second current detection range overlap with each other. When the controller 8 uses the first current as the detection current, that is, the first current is 100 A or smaller, the controller 8 corrects the first current by multiplying the first current by the gain correction value so as to calculate the detection current.

Thus, when the controller 8 calculates the detection current using the first current, the controller 8 can calculate the detection current in which the current detection error with respect to temperature change has been suppressed. Therefore, the controller 8 can improve the current detection accuracy.

As illustrated in FIG. 6, the controller 8 calculates the current ratio based on the first current and the second current that have been detected when the first current is equal to or larger than the predetermined threshold value, that is, the first current is equal to or larger than 90 A. The controller 8 calculates the gain correction value based on the calculated current ratio. Thus, the controller 8 can calculate the gain correction value using the first current in which the current detection error with respect to temperature change appears large.

As a result, the controller 8 can accurately calculate the gain correction value. Therefore, the controller 8 can improve the current detection accuracy

The controller 8 calculates the average value of the current ratio that has been calculated the predetermined number of times as the gain correction value. Thus, the controller 8 can accurately calculate the gain correction value. Therefore, the controller 8 can improve the current detection accuracy.

When the second switch 5 is open, the controller 8 may detect the first current and the second current, and perform a zero point correction for the first current sensor 6 and the second current sensor 7. For example, when the second switch 5 is open and the first current of 1 A has been detected, the controller 8 may correct the first current by subtracting 1 A from the first current.

A controller 8 according to a modification example detects a first current and a second current a predetermined number of times in the same timing. The controller 8 according to the modification example calculates an average value of the first current and an average value of the second current, which have been detected the predetermined number of times, and calculates a gain correction value by dividing the average value of the second current by the average value of the first current. According to the modification example, the same effect as the embodiment described above can be obtained.

The controller 8 according to the modification example calculates a current ratio when the first current falls within a first current detection range, the first current is larger than a predetermined threshold value and a change amount of the first current per unit time is smaller than a preset predetermined amount that shows current stability. That is, the controller 8 according to the modification example calculates the gain correction value using the first current and the second current that have been detected when the change amount of the first current per unit time is smaller than the predetermined amount. Thus, the controller 8 according to the modification example can calculate the gain correction value based on the current ratio calculated in a current-stable state. The controller 8 according to the modification example can, for example, suppress an error occurrence in the gain correction value by using a difference in response speed between a first current sensor 6 and a second current sensor 7. As a result, the controller 8 according to the modification example can accurately calculate the gain correction value. Therefore, the controller 8 according to the modification example can improve current detection accuracy of the first current.

When the controller 8 according to the modification example updates the gain correction value, the controller 8 according to the modification example gradually changes the gain correction value from a gain correction value before updating to a new gain correction value that has been calculated. For example, when the gain correction value before updating is 0.95 and the calculated new gain correction value is 0.90, the controller 8 according to the modification example updates the gain correction value from 0.95, 0.93 and 0.91 to 0.90. The controller 8 according to the modification example may set a change amount of the gain correction value to be equal to or smaller than an upper limit change amount that has been preset. Thus, when the controller 8 according to the modification example updates the gain correction value, the controller 8 according to the modification example can suppress an abrupt change in a detection current that is calculated by using the first current.

The controller 8 according to the modification example calculates the current ratio when the first current falls within the first current detection range and is larger than the predetermined threshold value, and an absolute value of a difference between the first current and the second current requires a correction, that is, a measuring error due to temperature change is larger than a preset predetermined value which is allowed. Namely, the controller 8 according to the modification example calculates the gain correction value based on the first current and the second current that have been detected when the absolute value of the difference between the first current and the second current is larger than the predetermined value. Thus, the controller 8 according to the modification example can suppress that the gain correction value is frequently calculated and updated even though the measuring error falls within an allowable range. Therefore, the controller 8 according to the modification example can decrease a load applied to the controller 8 according to the modification example.

The controller 8 according to the modification example determines that at least one of the first current sensor 6 and the second current sensor 7 is broken down when the absolute value of the difference between the first current and the second current is equal to or larger than an upper limit value. The upper limit value is a threshold value for determining a failure, which is larger than a predetermined value and is a preset value. Such a determination is performed by a determination portion 24. Thus, the controller 8 according to the modification example can detect the failure of the first current sensor 6 and the second current sensor 7. The controller 8 according to the modification example stops current detection when the controller 8 according to the modification example determines that at least one of the first current sensor 6 and the second current sensor 7 is broken down.

When it is determined that one of the first current sensor 6 and the second current sensor 7 has higher reliability than the other one, the controller 8 according to the modification example may use a value of a higher-reliability current sensor as the detection current to continue current detection. For example, when the first current is zero and the second current is not zero, while the LIB 3 is charging and discharging, the controller 8 according to the modification example determines that the reliability of the second current sensor 7 is higher than the first current sensor 6. When the controller 8 according to the modification example determines that the reliability of the second current sensor 7 is higher, the controller 8 according to the modification may use the second current as the detection current even in the first current detection range.

The controller 8 according to the modification example may decrement a calculation number of times from a predetermined number of times, and calculate the gain correction value, for example, when the calculation number of times reaches the predetermined number of times.

In this embodiment, the first current sensor 6 is used as a current sensor for detecting a small current, and the second current sensor 7 is used as a current sensor for detecting a large current. However, in the embodiment of the modification example, the first current sensor 6 may be used as a current sensor for detecting a large current, and the second current sensor 7 may be used as a current sensor for detecting a small current.

The controller 8 according to the modification example described above may be used in combination.

It is possible for a person skilled in the art to easily come up with more effects and modifications. Thus, a broader modification of this invention is not limited to specific description and typical embodiments described and expressed above. Therefore, various modifications are possible without departing from the general spirit and scope of the invention defined by claims attached and equivalents thereof.

While the invention has been shown and described in detail, the foregoing description is in all aspects illustrative and not restrictive. It is therefore understood that numerous other modifications and variations can be devised without departing from the scope of the invention.

What is claimed is:

1. A current detection apparatus comprising a microcomputer configured to:
detect a first current by using a first current sensor having a first current detection range;
detect a second current by using a second current sensor having a smaller current detection error with respect to temperature change than the first current sensor and having a second current detection range different from the first current detection range and partially overlapping the first current detection range;
calculate a correction value based on the second current that has been detected in a range in which the first current detection range and the second current detection range overlap with each other, and
correct the first current by the correction value when using the first current for a detection current to be detected.

2. The current detection apparatus according to claim 1,
wherein the microcomputer calculates the correction value based on the first current and the second current that have been detected when the first current is equal to or larger than a predetermined threshold value.

3. The current detection apparatus according to claim 2,
wherein the microcomputer calculates the correction value based on the first current and the second current that have been detected when a change amount of the first current per unit time is smaller than a predetermined amount.

4. The current detection apparatus according to claim 2,
wherein the microcomputer calculates the correction value based on the first current and the second current that have been detected when an absolute value of a difference between the first current and the second current is larger than a predetermined value.

5. The current detection apparatus according to claim 4,
wherein the microcomputer determines that at least one of the first current sensor and the second current sensor is broken down when the absolute value of the difference is equal to or larger than an upper limit value which is larger than the predetermined value.

6. The current detection apparatus according to claim 1,
wherein the microcomputer gradually changes the correction value to a new correction value when the new correction value has been calculated.

7. The current detection apparatus according to claim 6,
wherein the microcomputer sets a change amount of the correction value to be equal to or smaller than an upper limit change amount.

8. A current detection method comprising the steps of:
(a) detecting, by a microcomputer, a first current by using a first current sensor having a first current detection range;
(b) detecting, by the microcomputer, a second current by using a second current sensor having a smaller current detection error with respect to temperature change than the first current sensor and having a second current detection range different from the first current detection range and partially overlapping the first current detection range;
(c) calculating, by the microcomputer, a correction value based on the second current that has been detected in a range in which the first current detection range and the second current detection range overlap with each other; and
(d) correcting, by the microcomputer, the first current by the correction value when using the first current for a detection current to be detected.

9. The current detection method according to claim 8,
wherein the correction value is calculated based on the first current and the second current that have been detected when the first current is equal to or larger than a predetermined threshold value.

10. The current detection method according to claim 9,
wherein the correction value is calculated based on the first current and the second current that have been detected when a change amount of the first current per unit time is smaller than a predetermined amount.

11. The current detection method according to claim 9,
wherein the correction value is calculated based on the first current and the second current that have been detected when an absolute value of a difference between the first current and the second current is larger than a predetermined value.

12. The current detection method according to claim 11, further comprising determining, by the microcomputer, that at least one of the first current sensor and the second current sensor is broken down when the absolute value of the difference is equal to or larger than an upper limit value which is larger than the predetermined value.

13. The current detection method according to claim 8, further comprising gradually changing, by the microcomputer, the correction value to a new correction value when the new correction value has been calculated.

14. The current detection method according to claim 13,
wherein a change amount of the correction value is set to be equal to or smaller than an upper limit change amount.
